(19) United States
(12) Patent Application Publication
(10) Pub. No.: US 2026/0047417 A1
(43) Pub. Date: Feb. 12, 2026

(54) SEMICONDUCTOR PACKAGE

(71) Applicant: CXMT Corporation, Hefei City (CN)

(72) Inventors: LING-YI CHUANG, Hefei City (CN); Ying LIU, Hefei City (CN)

(73) Assignee: CXMT Corporation, Hefei City (CN)

(21) Appl. No.: 19/364,673

(22) Filed: Oct. 21, 2025

Related U.S. Application Data
(63) Continuation of application No. PCT/CN2025/083699, filed on Mar. 20, 2025.

(30) Foreign Application Priority Data
Apr. 18, 2024 (CN) 202410473944.4

(51) Int. Cl. H01L 23/00; H01L 23/31; H01L 23/48; H01L 25/065; H01L 25/16

(52) U.S. Cl. CPC H01L 24/32; H01L 23/3157; H01L 23/481; H01L 24/13; H01L 24/16; H01L 24/83; H01L 25/0657; H01L 25/16; H01L 2224/13; H01L 2224/16145; H01L 2224/32145; H01L 2224/83855

(57) ABSTRACT

Embodiments of the present disclosure provide a semiconductor package. The semiconductor package includes: a first semiconductor chip, a second semiconductor chip, and a first material layer arranged between the first semiconductor chip and the second semiconductor chip, where the first material layer includes a non-conductive substrate as well as a first-type filler and a second-type filler that are distributed in the non-conductive substrate, and the average particle size of the first-type filler is different from the average particle size of the second-type filler. In the embodiments of the present disclosure, two types of fillers with different particle sizes are utilized in combination to increase the filling ratio of the fillers and improve the CTE of the material layers.

### CROSS-REFERENCE TO RELATED APPLICATIONS

This is a continuation of International Patent Application No. PCT/CN2025/083699, filed on Mar. 20, 2025, which claims priority to Chinese Patent Application No. 202410473944.4, filed on Apr. 18, 2024. The disclosures of the above-referenced applications are hereby incorporated by reference in their entirety.

### BACKGROUND

The 3D stacking technology involves stacking a plurality of chips directly and vertically together, and communication and connection between the chips are implemented via silicon interconnection and packaging technology. Taking vertically stacked multilayer DRAM dies (die) as an example, each die layer is connected to a logic chip via the through-silicon-via (TSV) technology. The 3D integration technology makes it possible to package 8, 12, or even more layers of dies in a small volume of space, thereby achieving smaller dimensions, higher bandwidth, and higher reliability.

### SUMMARY

Embodiments of the present disclosure relate to the technical field of semiconductors, in particular to a semiconductor package.

Embodiments of the present disclosure provide a semiconductor package with higher reliability and performance.

According to an exemplary embodiment of the present disclosure, a semiconductor package includes: a first semiconductor chip; a second semiconductor chip arranged on the first semiconductor chip; and a first material layer arranged between the first semiconductor chip and the second semiconductor chip, where the first material layer includes a non-conductive substrate as well as a first-type filler and a second-type filler that are distributed in the non-conductive substrate, the average particle size of the first-type filler being different from the average particle size of the second-type filler.

According to another exemplary embodiment of the present disclosure, a semiconductor package includes: a buffer chip; a core chip arranged on the buffer chip; and a first material layer that at least partially surrounds the buffer chip and the core chip, where the first material layer includes a non-conductive substrate as well as a first-type filler and a second-type filler that are distributed in the non-conductive substrate, the average particle size of the first-type filler being different from the average particle size of the second-type filler.

### BRIEF DESCRIPTION OF DRAWINGS

The drawings, which are incorporated in and constitute a part of this specification, illustrate embodiments consistent with the embodiments of the present disclosure and, together with the specification, serve to explain the principles of the embodiments of the present disclosure.

FIG. 1 is a cross-sectional view of a semiconductor package according to an embodiment of the present disclosure;

FIG. 2A is a schematic structural diagram of a first material layer according to an embodiment of the present disclosure;

FIG. 2B is a schematic structural diagram of another first material layer according to an embodiment of the present disclosure;

FIG. 3 is a schematic diagram of a semiconductor package according to an embodiment of the present disclosure;

FIG. 4A is a schematic diagram of a semiconductor package according to an embodiment of the present disclosure;

FIG. 4B is a schematic diagram of a semiconductor package according to an embodiment of the present disclosure;

FIG. 5A is a schematic diagram of a semiconductor package according to an embodiment of the present disclosure;

FIG. 5B is a schematic diagram of a semiconductor package according to an embodiment of the present disclosure;

FIG. 5C is a schematic diagram of a semiconductor package according to an embodiment of the present disclosure;

FIG. 6 is a schematic diagram of a semiconductor package according to an embodiment of the present disclosure;

FIG. 7A is a schematic diagram of a semiconductor package according to the present disclosure;

FIG. 7B is a schematic diagram of a semiconductor package according to the present disclosure;

FIG. 8A is a schematic diagram of a semiconductor package according to the present disclosure;

FIG. 8B is a schematic diagram of a semiconductor package according to the present disclosure; and

FIG. 9 is a schematic diagram of a semiconductor package according to the present disclosure.

Through the above drawings, explicit embodiments of the embodiments of the present disclosure have been illustrated, and more detailed descriptions will follow. These drawings and textual descriptions are not intended to limit the scope of the inventive concept of the embodiments of the present disclosure in any way, but rather to explain the concepts of the embodiments of the present disclosure to those skilled in the art by referring to specific embodiments.

### DESCRIPTION OF EMBODIMENTS

The technical solutions in embodiments of the present disclosure will be clearly and completely described below with reference to the drawings in the embodiments of the present disclosure. It can be understood that the specific embodiments described herein are merely illustrative of the related disclosures and are not intended to limit the present disclosure. In addition, it should be further noted that for the convenience of description, only the relevant portions are shown in the drawings. Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure. In the following description, reference is made to “some embodiments” which describe subsets of all possible embodiments, but it can be understood that “some embodiments” may be the same subset or different subsets of all possible embodiments, and may be combined with each other without conflict. It should be noted that the terms “first\second\third” referred to in the embodiments of the present disclosure are merely used for distinguishing similar objects and do not represent a specific ordering for the objects. It can be understood that “first\second\third” may be subjected to interchange of a specific order or sequence if permitted, such that the embodiments of the present disclosure described herein can be implemented in an order other than that shown or described.

The embodiments of the present disclosure are described in detail below with reference to the drawings.

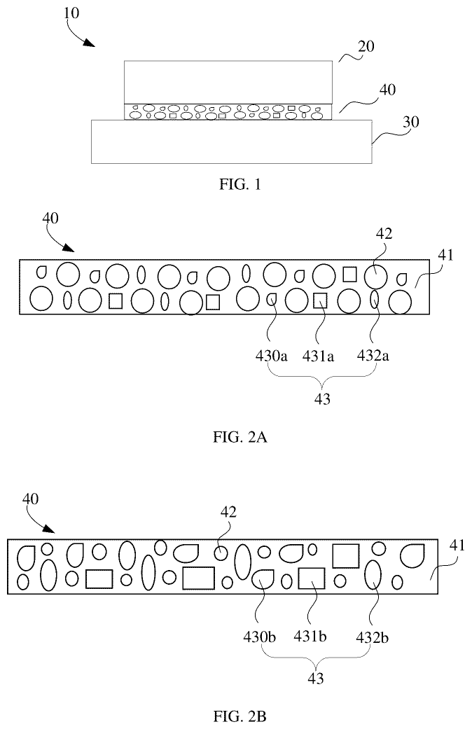

In an embodiment of the present disclosure, referring to FIG. 1, FIG. 1 provides a cross-sectional view of a semiconductor package, and the semiconductor package 10 includes a first semiconductor chip 30 and a second semiconductor chip 20 located on the first semiconductor chip 30. A first material layer 40 is arranged between the first semiconductor chip 30 and the second semiconductor chip 20, and the first material layer 40 is used to implement a fixed connection between the first semiconductor chip 30 and the second semiconductor chip 20.

In some embodiments, the first semiconductor chip 30 is provided with a surface opposite to the second semiconductor chip 20, and the first material layer 40 may be first arranged in the form of a thin film on the surface of the first semiconductor chip 30 opposite to the second semiconductor chip 20, so as to achieve the fixed connection between the first semiconductor chip 30 and the second semiconductor chip 20.

In some embodiments, the second semiconductor chip 20 is provided with a surface opposite to the first semiconductor chip 30, and the first material layer 40 may be first arranged in the form of a thin film on the surface of the second semiconductor chip 20 opposite to the first semiconductor chip 30, so as to achieve the fixed connection between the first semiconductor chip 30 and the second semiconductor chip 20.

In some embodiments, the first material layer 40 is first partially arranged on the respective opposing surfaces of both the first semiconductor chip 30 and the second semiconductor chip 20. The fixed connection between the first semiconductor chip 30 and the second semiconductor chip 20 is achieved through the partial first material layer 40 on the first semiconductor chip 30 and the partial first material layer 40 on the second semiconductor chip 20.

In some embodiments, the first semiconductor chip 30 and the second semiconductor chip 20 may each be one of the following: a logic chip represented by a gate array, a cell base array (cell base array), an embedded array, a structured application specific integrated circuit (ASIC), a field programmable gate Array (FPGA), a complex programmable logic device (CPLD), a central processing unit (CPU), a micro processing unit (MPU), a micro controller unit (MCU), a logic IC, an application processor (AP), a driver IC, an RF chip, and a CMOS image sensor, or a memory chip represented by a DRAM and a NAND, and the present disclosure is not limited thereto.

In some embodiments, the first semiconductor chip 30 and the second semiconductor chip 20 may be the same, for example, the first semiconductor chip 30 and the second semiconductor chip 20 are both memory chips or logic chips.

In some embodiments, the first semiconductor chip 30 and the second semiconductor chip 20 may also be different, for example, the first semiconductor chip 30 is a logic chip and the second semiconductor chip is a memory chip.

In some embodiments, referring to FIGS. 2A and 2B, the first material layer 40 includes a substrate 41, and the substrate 41 may be a sealing material that enables the first semiconductor chip 30 and the second semiconductor chip 20 to bond with each other. Examples of such a material include a silicon-based material, a thermosetting material, a thermoplastic material, an ultraviolet (UV) curing material, or other non-conductive materials. In addition, a hardener, a polymer, a flux (a soldering flux), or other additives for assisting the first material layer 40 in achieving the sealing and bonding effect are further present in the substrate 41, which will not be repeated here.

The first material layer 40 further includes a first-type filler 42 and a second-type filler 43 distributed in the substrate 41. The first-type filler 42 and the second-type filler 43 are distributed relatively uniformly in the substrate 41. The first-type filler 42 and the second-type filler 43 are mainly used to control the coefficient of thermal expansion (CTE), the viscosity, Young's modulus, and other properties of the first material layer 40.

In some embodiments, the first-type filler 42 and the second-type filler 43 have different particle size distributions.

In some embodiments, referring to FIG. 2A, the average particle size of the first-type filler 42 is greater than the average particle size of the second-type filler 43. The first-type filler 42 includes a type of particles with substantially the same geometric structure, e.g., circular or approximately circular, and the particle sizes of these particles may be normally distributed. The second-type filler 43 includes particles 430a, particles 431a, and particles 432a; the geometric structures of particles 430a, particles 431a, and particles 432a may be the same or different, e.g., particles 430a, particles 431a, and particles 432a may be provided with non-circular or irregular geometric structures. In some embodiments, the particle sizes of particles 430a, particles 431a, and particles 432a are distributed non-normally, i.e., the average particle sizes of particles 430a, particles 431a, and particles 432a are different from each other.

In some embodiments, the average particle size of the first-type filler 42 is about 2-5 times the average particle size of the second-type filler. In other embodiments, the average particle size of the first-type filler 42 is about 2.5-3 times or 3-3.5 times the average particle size of the second-type filler.

In some embodiments, referring to FIG. 2B, the average particle size of the first-type filler 42 is smaller than the average particle size of the second-type filler 43. The first-type filler 42 includes a type of particles with substantially the same geometric structure, e.g. circular, oval, or ellipsoidal, and the particle sizes of these particles may be normally distributed. The second-type filler 43 includes particles 430b, particles 431b, and particles 432b, and the geometric structures of particles 430b, particles 431b, and particles 432b may be the same or different. For example, particles 430b, particles 431b, and particles 432b may be provided with non-circular or irregular geometric structures, e.g. planar, i.e., flake-like, irregular, or prismatic. In some embodiments, the particle sizes of particles 430b, particles 431b, and particles 432b are distributed non-normally, i.e., the average particle sizes of particles 430b, particles 431b, and particles 432b are different from each other.

In some embodiments, the average particle size of the second-type filler 42 is about 2-5 times the average particle size of the first-type filler. In other embodiments, the average particle size of the second-type filler 42 is about 2.5-3 times or 3-3.5 times the average particle size of the first-type filler.

In these embodiments, by providing the first-type filler and the second-type filler with different average particle sizes, the first material layer is made superior, in terms of coefficient of thermal expansion (CTE), viscosity, Young's modulus, and other properties, to a material using the same type of filler. This is because, as the package volume is further miniaturized, the distance between chips becomes smaller, and the density of the electrically connected parts between chips is further increased, leading to higher requirements for the CTE, viscosity, Young's modulus, and other properties of the material layer for fixing the chips. Generally speaking, as the ratio of the filler in the material layer increases, the CTE of the material layer will decrease, which will be beneficial to improve the packaging reliability of the package and reduce the risk of issues such as delamination. The conventional way of increasing the filling ratio of the filler is to decrease the particle size of the filler, but the decrease of the particle size, especially for the filler maintaining a regular geometric structure at a small particle size, will increase the production cost. Therefore, in these embodiments of the present disclosure, two types of fillers with different particle sizes are utilized in combination, and the filler with a large particle size drives the filler with a small particle size to flow in the substrate, improving the uniformity of the small-particle-sized filler. The small-particle-sized fillers can be distributed in gaps formed by the large-particle-sized fillers, increasing the filling rate of the filler and improving the CTE of the material layer. Additionally, the combined use of fillers with both large and small particle sizes allows the fillers to not strictly require a regular geometric structure, thereby further reducing costs.

In some embodiments, the first-type filler 42 and the second-type filler 43 may both be one or more types of inorganic fillers, such as silica, aluminum oxide, aluminum nitride, boron nitride, silicon nitride, silicon carbide, magnesium oxide, or zinc oxide. In some embodiments, the first-type filler 42 may be a silicon-containing inorganic filler, such as silica, silicon nitride, or silicon carbide, optionally spherical silica; the second-type filler 43 may be a composite filler containing metallic elements, such as aluminum oxide, aluminum nitride, boron nitride, magnesium oxide, or zinc oxide, optionally magnesium oxide, zinc oxide, or aluminum nitride.

In some embodiments, by using the second-type filler containing metallic elements, the thermal conductivity of the first material layer can be effectively increased. In some embodiments, by using the second-type filler that has a smaller particle size and contains metallic elements, the thermal conductivity of the first material layer can be increased and the CTE of the first material layer can be decreased.

In some embodiments, the volume fraction of the first-type filler 42 in the substrate 41 is greater than the volume fraction of the second-type filler 43 in the substrate 41.

In some embodiments, the volume ratio of the first-type filler 42 to the second-type filler 43 ranges from 2 to 4.5, e.g., the volume ratio of the two fillers may be 2-3 or 3-4.

In these embodiments, by setting the volume fraction of the first-type filler in the substrate to be greater than the volume fraction of the second-type filler in the substrate, it can be ensured that the second-type filler is propelled to flow in the substrate by the first-type filler during its flow in the substrate, thereby improving the uniformity of distribution of the fillers with irregular geometric structures in the substrate.

In some embodiments, the combined use of the second-type filler with a relatively smaller volume fraction and the first-type filler with a larger volume fraction and better surface profile can reduce the increase in light scattering through the substrate caused by the second-type filler with irregular geometric structures. This decreases the risk of reducing the light transmittance of the first material layer. As a result, during the soldering alignment between the first semiconductor chip and the second semiconductor chip, the introduction of the second-type filler will not make it difficult to identify the pattern or position display using the camera.

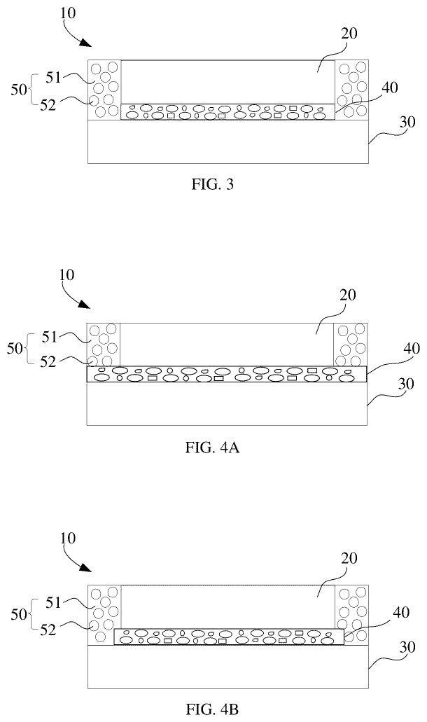

In some embodiments, referring to FIG. 3, the chip area of the first semiconductor chip 30 is greater than the chip area of the second semiconductor chip 20, and the first material layer 40 between the first semiconductor chip 30 and the second semiconductor chip 20 does not completely cover the surface of the first semiconductor chip 30. In these embodiments, the semiconductor package 10 further includes a third material layer 50 on the first semiconductor chip 30, and the third material layer 50 encloses the second semiconductor chip 20 and the first material layer 40 to further enhance the sealing effect on the first semiconductor chip 30 and the second semiconductor chip 20.

In some embodiments, the third material layer 50 includes a substrate 51 and a filler 52 distributed in the substrate 51. The third material layer 50 may be an insulating layer, such as a silicon material or an epoxy resin material. The substrate 51 may be a material that is the same as or different from the substrate 41 of the first material layer 40, specifically, it may be a material that, after treatment with light, heat, and/or pressure, enables the bonding of the first semiconductor chip and the second semiconductor chip, e.g., an insulating material with sealing performance such as a silicon material or an epoxy resin material. In some embodiments, the filler 52 may be one or a mixture of silica, aluminum oxide, aluminum nitride, boron nitride, silicon nitride, silicon carbide, magnesium oxide, zinc oxide, and the like.

In some embodiments, the particle material of the filler 52 may include any suitable particle geometric structures, such as, but not limited to, spherical, oval, ellipsoidal, and planar (i.e., flake-like, irregular, or prismatic). The average particle size of these particles is greater than the average particle size of the filler 42 and the filler 43 in the first material layer 40.

In some embodiments, the volume fraction of the filler 52 in the substrate 51 is less than the sum of the volume fractions of the filler 42 and the filler 43 in the non-conductive substrate 41. For example, in some embodiments, the volume fraction of the filler 52 in the substrate 51 is 20%-60%, optionally 35%, 40%, or 50%. The total volume fraction of the filler 42 and the filler 43 in the non-conductive substrate 41 is 35%-70%, optionally 45%, 50%, or 60%. In other embodiments, the value of the volume fraction of the filler 52 in the substrate 51 is not less than 50%-80% of the value of the volume fraction of the filler 42 and filler 43 in the non-conductive substrate 41. For example, in some embodiments, the total volume fraction of the filler 42 and the filler 43 in the non-conductive substrate 41 is 50%-80%, then, the volume fraction of the filler 52 in the substrate 51 is not less than 25%-40%.

In some embodiments, the third material layer 50 may, after the first semiconductor chip 30 and the second semiconductor chip 20 are sealed via the first material layer 40, enclose the second semiconductor chip 20, the first material layer 40, and the partially exposed surface of the first semiconductor chip 30 by filling methods such as molding reflow, to form the sealed package 10.

In these embodiments, by arranging a third material layer with a larger average filler particle size and a smaller filler volume fraction to enclose the first material layer and the parts of the first semiconductor chip and the second semiconductor chip that are not enclosed by the first material layer, on the one hand, the difference in the filler particle size can increase the packaging stability of the entire package at a lower cost; on the other hand, the difference in the filler volume fraction can address the issue of CTE imbalance among the various components during sealing. The delamination caused by an excessive difference in CTE between the first material layer, the third material layer, and the semiconductor chip during the thermal treatment of the first material layer and the third material layer is prevented, and the reliability of the package is prevented from being affected.

To make the contents of the present disclosure clearer, the process of forming a semiconductor package is further described below.

In some embodiments, forming the semiconductor package 10 includes the following steps.

In S11, a first-type filler and a second-type filler are provided, and the first-type filler and the second-type filler are mixed into a non-conductive substrate. The first-type filler and the second-type filler are uniformly mixed and cured in the non-conductive substrate by methods such as stirring, to form a film-like first material layer.

In S13, a wafer is provided, and one surface of the film-like first material layer is attached to the surface of the wafer. In some embodiments, the surface of the wafer that is attached to the first material layer is provided with contacts for transmitting signals or power supply, and these contacts enter into the first material layer through the surface of the first material and do not protrude from the first material layer. In some embodiments, the wafer may be a wafer including a plurality of dies, or may be a single die or other bearing structures, such as a carrier wafer.

In S15, another wafer is provided, the wafer with the first material layer attached is turned over, the other surface of the first material layer is attached to one surface of the other wafer, and the two wafers are attached and fixed by the first material layer after thermal compression treatment. In some embodiments, the surface of the other wafer is provided with contacts for transmitting signals or power supply. After the two wafers are attached, the contacts on their respective surfaces are combined with each other, and the first material layer surrounds the combined contacts, so that insulation between adjacent contacts is achieved.

In some embodiments, the wafer provided in S15 may be a wafer including a plurality of dies, or may be a single die or other bearing structures, such as a carrier wafer.

In some embodiments, the wafer in S13 is a wafer including a plurality of dies, and when the wafer is turned over in step S15, the wafer with the first material layer attached is cut first to form a plurality of second semiconductor chips separated from each other; the wafer provided in S15 is a single die, i.e., a first semiconductor chip.

In some embodiments, the wafer in S13 is a wafer including a plurality of dies, and when the wafer is turned over in step S15, the wafer with the first material layer attached is cut first to form a plurality of second semiconductor chips separated from each other; the wafer provided in S15 is a wafer including a plurality of dies, and after step S15 is completed, a singulation step is further included to divide the other wafer provided in S15 into a plurality of first semiconductor chips, that is, the second semiconductor chips are first attached to the wafer including the first semiconductor chips, and then the first semiconductor chips are separated to obtain a package in which a first semiconductor chip and a second semiconductor chip are combined.

In these embodiments, the first semiconductor chip and the second semiconductor chip may be chips with different areas.

In some embodiments, the first material layer may be first formed on the first semiconductor chip or the wafer including the first semiconductor chip, and then the first semiconductor chip or the wafer including the first semiconductor chip is attached to the second semiconductor chip or the wafer including the second semiconductor chip via the first material layer.

The method for forming the package of the present disclosure is not limited thereto and is not described herein again.

In some embodiments, since the first material layer is first formed on the first semiconductor chip or the second semiconductor chip, and the thermal compression bonding (Thermal Compression Bonding, TCB) process adopted in the attachment of the first semiconductor chip and the second semiconductor chip involves temperature increase and decrease as well as pressure changes. In this process, the first material layer initially exhibits a certain fluidity under a temperature lower than a hardening temperature thereof, enabling the first material layer to enclose the first semiconductor chip and the second semiconductor chip. Subsequently, the first material layer is hardened at the hardening temperature of the first material layer. In this process, the first material layer may have a part that overflows beyond the first semiconductor chip or the second semiconductor chip. In some implementations, considering the problem of CTE mismatch between the chip and the material used for bonding the chip, the bonding pressure is controlled during the TCB process to prevent more material from overflowing onto the surfaces of the chips that are not in direct contact. However, for the sealing effect of the chips, excessive overflowing material can effectively ensure that a sufficient amount of insulating sealing material is provided between the dense contacts between the chips. The first material layer according to the embodiments of the present disclosure can effectively address the CTE problem under the condition of excessive overflowing, so that better packaging reliability is achieved.

With continued reference to FIGS. 4A and 4B, FIG. 4A illustrates a schematic structural diagram of a package 10, where the first material layer is first formed on the first semiconductor chip. Since the first material layer 40 is already formed on the first semiconductor chip 30 prior to the bonding of the first semiconductor chip 30 and the second semiconductor chip 20, the third material layer 50 formed after bonding the first semiconductor chip 30 and the second semiconductor chip 20 has a first contact surface directly abutting against the first material layer 40, and the second semiconductor chip 20 has a surface not covered by the first material layer 40. In some embodiments, the side walls of the second semiconductor chip 20 may also be covered by part of the first material layer 40, i.e., the part of the first material layer 40 at the outer periphery of the second semiconductor chip 20 is provided with a protruding part, and the protruding part may enclose part of the surface of the side walls of the second semiconductor chip 20.

In some embodiments, the third material layer 50 has a second contact surface that directly contacts the second semiconductor chip 20, and the surface area of the first contact surface is greater than the surface area of the second contact surface.

In some embodiments, as shown in FIG. 4A, the first material layer 40 may have an edge that is not covered by the third material layer 50.

With continued reference to FIG. 4B, FIG. 4B illustrates a schematic structural diagram of a package 10, where the first material layer is first formed on the second semiconductor chip. Since the first material layer 40 is first formed on the second semiconductor chip 20 prior to the bonding of the first semiconductor chip 30 and the second semiconductor chip 20, during the TCB process of bonding the first semiconductor chip 30 and the second semiconductor chip 20, the first material layer 40 has a part that overflows beyond the second semiconductor chip 20. The third material layer 50 formed thereafter is provided with both a first contact surface directly abutting the first material layer 40 and a third contact surface directly abutting the first semiconductor chip 30, and the second semiconductor chip 20 is provided with a surface not covered by the first material layer 40. In some embodiments, the side walls of the second semiconductor chip 20 may also be covered by part of the first material layer 40, i.e., the part of the first material layer 40 at the outer periphery of the second semiconductor chip 20 is provided with a protruding part, and the protruding part may enclose part of the surface of the side walls of the second semiconductor chip 20.

In some embodiments, the third material layer 50 has a second contact surface that directly contacts the second semiconductor chip 20, and the surface area of the first contact surface is greater than the surface area of the second contact surface.

In some embodiments, the surface area of the third contact surface is less than the surface area of the first contact surface.

In these embodiments, since the CTE of the provided first material layer is closer to that of the third material layer, after thermal compression treatment, the direct contact area between the first material layer and the third material layer is greater than the direct contact area between the third material layer and the second semiconductor chip. As a result, the formed package exhibits better packaging reliability.

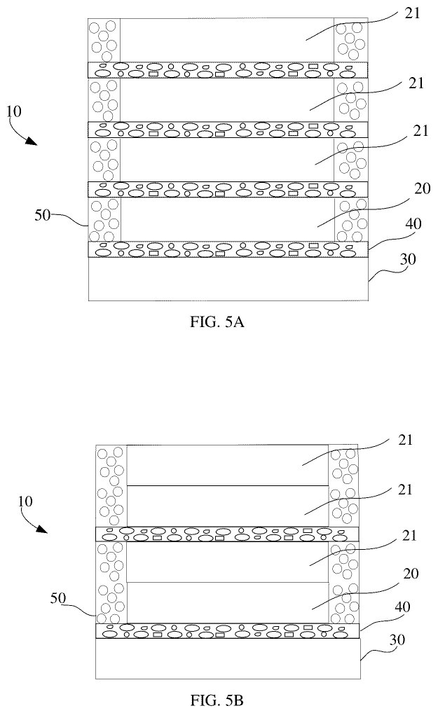

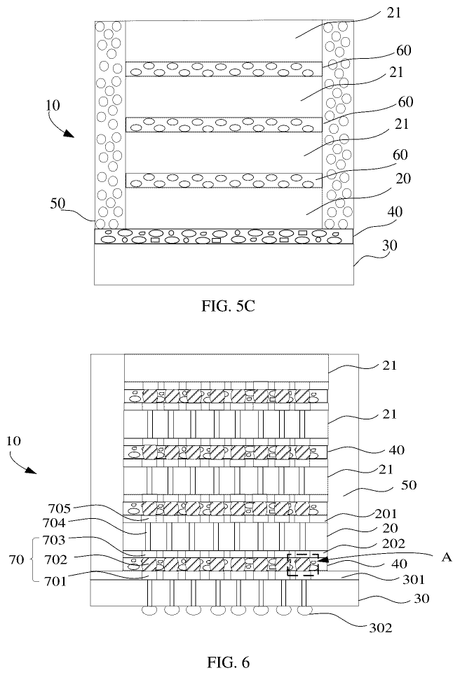

In some embodiments, referring to FIGS. 5A, 5B, and 5C, the semiconductor package 10 further includes a plurality of third semiconductor chips 21 arranged on the second semiconductor chip 20, where one surface of the third semiconductor chip 21 closest to the second semiconductor chip 20 is directly aligned and attached to the second semiconductor chip 20, and the surface of the third semiconductor chip 21 not attached to the second semiconductor chip 20 is provided with the first material layer 40. The number of the third semiconductor chips 21 may be three or more than three, e.g., seven, eleven, etc. As an illustration, in the present disclosure, the number of the third semiconductor chips is three, but not limited thereto. The third semiconductor chip 21 may be a chip of the same type as or a different type from the second semiconductor chip 20. For example, the third semiconductor chip 21 and the second semiconductor chip 20 are both memory chips.

In some embodiments, referring to FIG. 5A, the attachment between the second semiconductor chip 20 and the third semiconductor chip 21 is achieved via the first material layer 40. The first material layer 40 is also arranged between each of the third semiconductor chips 21 to achieve attachment. Meanwhile, a third material layer 50 encloses the periphery of each third semiconductor chip 21. In some embodiments, the first material layer partially covers the surfaces of the second semiconductor chip and the third semiconductor chip, i.e., the third material layer 50 also encloses the outer periphery of each first material layer 40 at the same time. In the embodiments, by the overlapping use of the first material layer and the third material layer, the stress generated by multiple times of thermal compression treatments in multi-chip stacking is effectively balanced, and better packaging reliability is achieved.

In some embodiments, referring to FIG. 5B, the second semiconductor chip 20 and the third semiconductor chip 21 are not attached via the first material layer but instead are attached and fixed using a surface direct bonding method. For example, the fixation between the chips is achieved by fusion bonding (fusion bonding), or the fixation and electrical connection between the chips are achieved simultaneously by hybrid bonding (hybrid bonding). In some embodiments, the attachment between adjacent sets of third semiconductor chips 21 may also be achieved by a direct bonding method or by arranging a first material layer. As shown in FIG. 5B, the first third semiconductor chip 21 and the second semiconductor chip 20 are attached by a direct bonding method, the second third semiconductor chip 21 and the first semiconductor chip 21 are attached via the first material layer 40, and the third semiconductor chip 21 and the second third semiconductor chip 21 are attached by a direct bonding method. The third material layer 50 encloses the second semiconductor chip 20 and the periphery of the plurality of third semiconductor chips at the same time. In some embodiments, the first material layer partially covers the surfaces of the second semiconductor chip and the third semiconductor chip, i.e., the third material layer 50 also encloses the outer periphery of each first material layer 40 at the same time. In these embodiments, in addition to continuing to use the CTE-matched first material layer and third material layer for sealing, at least two chips are attached by a direct bonding method, so that the dimensions of the package can be further miniaturized, and the capacity of the package can be expanded.

In some embodiments, referring to FIG. 5C, the attachment between the second semiconductor chip 20 and the third semiconductor chip 21 is not achieved via the first material layer but instead by arranging the second material layer 60. The second material layer 60 includes a resin-based substrate and a filler dispersed in the substrate. The filler in the second material layer 60 may have the same particle size distribution, type, and volume fraction as the filler 42 in the first material layer 40, which will not be described here again. In some embodiments, at least two third semiconductor chips are attached by arranging the second material layer 60. FIG. 5C illustrates an embodiment in which all the third semiconductor chips are attached to each other by the second material layer 60. The third material layer 50 encloses the outer peripheries of the second semiconductor chip 20 and the third semiconductor chips 21, and at the same time, the outer peripheries of the first material layer 40 and the second material layer 60 are also enclosed by the third material layer 50. In these embodiments, the cost can be further lowered by using the second material layer to replace part of the first material layer.

The present disclosure further provides a package 10. In some embodiments, referring to FIG. 6, the package 10 includes a first semiconductor chip 30, a second semiconductor chip 20, a plurality of third semiconductor chips 21, and conductive structures 70 connecting the chips. The first semiconductor chip 30 and the second semiconductor chip 20 are attached via the first material layer 40, the second semiconductor chip 20 and the third semiconductor chip 21 are attached via the first material layer 40, and the third semiconductor chips 21 are attached to each other via the first material layer 40. A third material layer 50 encloses the space between the chips that is not enclosed by the first material layer 40.

In some embodiments, the chips may also be attached via a second material layer, and the positions of the first material layer and the third material layer may be arranged in the manner described above, which is not specifically limited herein.

With continued reference to FIG. 6, in some embodiments, each conductive structure 70 includes a contact pad 701 arranged on the surface of the first semiconductor chip 30, the contact pad 701 being connected to the circuit structure in the first semiconductor chip 20. The conductive structure 70 further includes a contact pad 703 arranged in the surface dielectric layer 202 of the second semiconductor chip 20 and an intermediate interconnection structure 702 connecting the contact pad 703 and the contact pad 701, the contact pad 703 being connected to the circuit structure in the second semiconductor chip 20. In these embodiments, the first material layer 40 encloses the intermediate interconnection structure 702. The contact pad 703 and the contact pad 701 are not enclosed by the first material layer 40.

In some embodiments, the first contact pad 701 and the second contact pad 703 may be a metal such as copper (Cu), nickel (Ni), tungsten (W), aluminum (Al), or an alloy.

In some embodiments, the intermediate interconnection structure 702 may be a solder including one or more of tin (Sn), titanium (Ti), vanadium (V), antimony (Sb), lead (Pb), tungsten (W), chromium (Cr), copper (Cu), nickel (Ni), aluminum (Al), palladium (Pd), silver (Ag), and gold (Au).

With continued reference to FIG. 6, in some embodiments, the surface of the first semiconductor chip 30 is provided with a dielectric layer 301, and the contact pad 701 is arranged in the dielectric layer 301. The two opposing surfaces of the second semiconductor chip 20 are provided with a dielectric layer 201 and a dielectric layer 202, respectively; the contact pad 703 is arranged in the dielectric layer 202, and the contact pad 705 is arranged in the dielectric layer 201; the contact pad 703 and the contact pad 705 are interconnected through an interconnection via 704 provided in the second semiconductor chip 20. As a result, the electrical connection between the first semiconductor chip 30 and the second semiconductor chip 20 is achieved. The other side of the first semiconductor chip 30 is also provided with solder balls 302, which are configured to interconnect the first semiconductor chip 30 with other structures, such as a silicon interposer or a PCB circuit board.

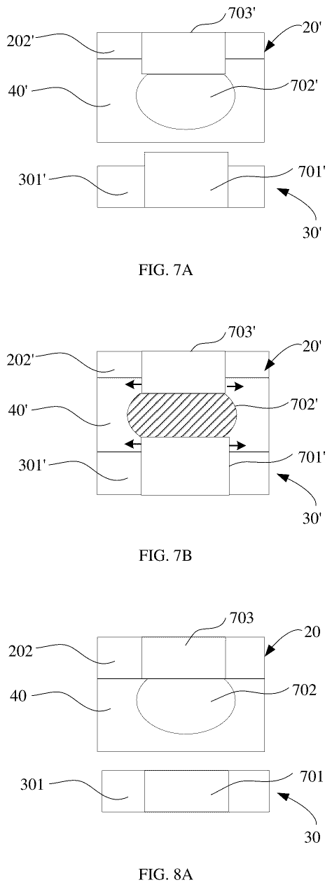

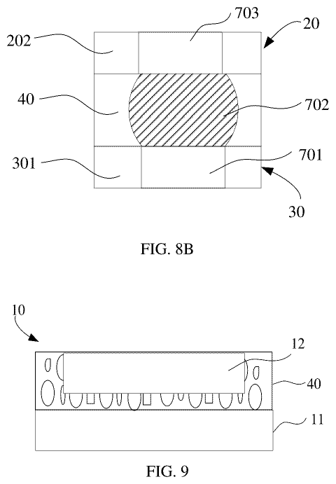

The beneficial effects of these embodiments are further described below with specific reference to FIGS. 7A-7B and 8A-8B.

FIGS. 7A and 7B are schematic diagrams of some embodiments of the present disclosure. As shown in FIG. 7A, a first material layer 40′ is arranged on a chip 20′ prior to the attachment of a chip 30′ and the chip 20′; a contact pad 701′ is arranged in a dielectric layer 301′ on the surface of the chip 30′ and is provided with a part protruding from the surface of the chip 30′, and a contact pad 703′ is arranged in a dielectric layer 202′ on the surface of the chip 20′ and is provided with a part protruding from the surface of the chip 20′. An intermediate interconnection structure 702′ is formed on the contact pad 703′ and is enclosed by the first material layer 40′. As shown in FIG. 7B, the chip 30′ and the chip 20′ are interconnected via the first material layer 40′ under the action of a thermal compression bonding device. The intermediate interconnection structure 702′ is connected to the contact pad 701′. During the thermal compression treatment process, the intermediate interconnection structure 702′ undergoes greater deformation relative to the contact pad 701′ and the contact pad 703′, forming an interface protruding from the contact pad 701′ and the contact pad 703′. The deformed interface and part of the interface of each contact pad are arranged in the first material layer 40′. This causes the force of the intermediate interconnection structure 702′ pressing the first material layer 40′ during the deformation process to simultaneously press the first material layer 40′ on the surface of each contact pad outward, as shown by the black arrows in FIG. 7B. This results in the risk of delamination between the first material layer 40′ and the surface of each contact pad, thereby reducing the packaging reliability.

FIGS. 8A-8B are enlarged partial views of region A in FIG. 6. As shown in FIG. 8A, prior to an attachment, the contact pad 701 of the first semiconductor chip 30 and the contact pad 703 of the second semiconductor chip 20 are respectively arranged in the dielectric layer 202 and the dielectric layer 301. The first material layer 40 is formed on the surface of the dielectric layer 202 of the second semiconductor chip 20 and encloses the intermediate interconnection structure 702 formed on the contact pad 703. As shown in FIG. 8B, under the action of the thermal compression bonding device, since the contact pad 701 and the contact pad 703 are arranged in the dielectric layers on the surfaces of their respective chips and do not contact with the first material layer 40, in the deformation process of the intermediate interconnection structure 702, the sealing effect of the contact pad 701 and the contact pad 703 is not affected, and the risk caused by relatively large deformation of the intermediate interconnection structure 702 is avoided. In addition, the first material layer 40 in the embodiments of the present disclosure adopts a composite filler with a lower CTE, so that the deformation of the intermediate interconnection structure 702 can be effectively resisted. This prevents the sealing problem caused by the interface between the first material layer 40 and the intermediate interconnection structure 702 becoming more complex, and avoids short circuits between adjacent intermediate interconnection structures 702.

The above description of the beneficial effects is only the presentation of one of the technical effects of the embodiments of the present disclosure and is not to be construed as any limitation to the technical solutions of the embodiments.

In some embodiments, as shown in FIG. 6, the first material layer 40 may be first arranged on the second semiconductor chip 20, and then the first third semiconductor chip 21 is stacked on the second semiconductor chip 20; subsequently, the first material layer 40 is arranged on the surface of the first third semiconductor chip 21 distal to the second semiconductor chip 20, and then the second third semiconductor chip 21 is stacked on the surface of the first third semiconductor chip 21 containing the first material layer. This process is repeated to realize the stacking of a plurality of third semiconductor chips 21.

In some embodiments, the first material layer 40 may be first arranged on the surface of the first third semiconductor chip 21 facing the second semiconductor chip 20, and then this surface is attached to the second semiconductor chip 20, so that the attachment between the second semiconductor chip 20 and the first third semiconductor chip 21 is achieved; subsequently, the first material layer 40 is arranged on one surface of the second third semiconductor chip 21, and this surface is attached to the surface of the first third semiconductor chip 21 distal to the second semiconductor chip 20, so that the attachment between the first third semiconductor chip 21 and the second semiconductor chip 21 is achieved. This process is repeated to realize the stacking of a plurality of third semiconductor chips 21.

In some embodiments, after the stacking of the first semiconductor chip 30, the second semiconductor chip 20, and the plurality of third semiconductor chips 21 is completed, the third material layer 50 is formed simultaneously at the outer peripheries of the chip stack and each first material layer 40 by one-step injection filling. In some embodiments, the third material layer 50 may also enclose the chip stack in other ways known to those skilled in the art, which will not be repeated here.

In some embodiments, the package 10 further includes an interconnection structure that connects the second semiconductor chip 20 to the third semiconductor chip 21 and connects each third semiconductor chip 21. These interconnection structures may utilize the same interconnection structure as that between the first semiconductor chip 30 and the second semiconductor chip 20. In some other embodiments, other connection methods for interconnecting chips that can be understood by those skilled in the art may also be adopted, which will not be repeated here.

Some embodiments of the present disclosure further provide another semiconductor package 10. Referring to FIG. 9, the semiconductor package includes a buffer chip 11, a core chip 12 arranged on the buffer chip 11, and a first material layer 40 surrounding both the buffer chip 11 and the core chip 12. The first material layer 40 is the first material layer 40 adopted in the above embodiments.

To make the contents of the semiconductor package 10 clearer, the process of forming the semiconductor package 10 is further described below.

In some embodiments, forming the semiconductor package 10 includes the following steps.

In S21, a first-type filler and a second-type filler are provided, and the first-type filler and the second-type filler are mixed into a non-conductive substrate. The first-type filler and the second-type filler are uniformly mixed in the non-conductive substrate by methods such as stirring, to obtain a first material layer 40.

In S23, a buffer chip 11 and a core chip 12 are provided, contacts that are spaced apart from each other are arranged on the surfaces of the buffer chip 11 and the core chip 12, and the contacts of the buffer chip 11 and the core chip 12 are in one-to-one correspondence to complete pre-bonding.

In S25, the first material layer 40 is filled into the gap between the pre-bonded buffer chip 11 and core chip 12 using a reflow filling process, and then the buffer chip 11 and the core chip 12 are attached using a curing process.

The first material layer 40 formed through the above steps encloses both the buffer chip 11 and the core chip 12. The package formed according to these embodiments exhibits good performance due to the lower CTE and better thermal conductivity of the manufactured first material layer 40.

In some embodiments, the core chip 12 may be a stack of a plurality of core chips, with the first material layer 40 simultaneously enclosing the stack. In some embodiments, the buffer chip 11 may be a logic chip represented by a gate array, a cell base array (cell base array), an embedded array, an application specific integrated circuit (ASIC), a field programmable gate array (FPGA), a complex programmable logic device (CPLD), a central processing unit (CPU), a micro processing unit (MPU), a micro controller unit (MCU), a logic IC, an application processor (AP), a driver IC, an RF chip, and a CMOS image sensor. The core chip 12 may be a memory chip represented by a DRAM, which will not be repeated here.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A semiconductor package, comprising:
a first semiconductor chip;
a second semiconductor chip arranged on the first semiconductor chip; and
a first material layer arranged between the first semiconductor chip and the second semiconductor chip, wherein
the first material layer comprises a non-conductive substrate as well as a first-type filler and a second-type filler that are distributed in the non-conductive substrate, an average particle size of the first-type filler being different from an average particle size of the second-type filler.

2. The semiconductor package according to claim 1, wherein the first-type filler does not contain a metallic element, the second-type filler contains a metallic element, and the average particle size of the first-type filler is greater than the average particle size of the second-type filler.

3. The semiconductor package according to claim 2, wherein the average particle size of the first-type filler is 2-3 times the average particle size of the second-type filler.

4. The semiconductor package according to claim 1, wherein a volume fraction of the first-type filler in the non-conductive substrate is greater than a volume fraction of the second-type filler in the non-conductive substrate.

5. The semiconductor package according to claim 4, wherein a volume ratio of the first-type filler to the second-type filler ranges from 2 to 4.5.

6. The semiconductor package according to claim 1, further comprising a third material layer, wherein the third material layer is arranged on the first semiconductor chip, and the third material layer comprises a substrate and a third-type filler distributed in the substrate, an average particle size of the third-type filler being greater than the average particle size of the first-type filler and the average particle size of the second-type filler.

7. The semiconductor package according to claim 6, wherein the third material layer and the first material layer have a first contact surface, and the third material layer and the second semiconductor chip have a second contact surface, a surface area of the first contact surface being greater than a surface area of the second contact surface.

8. The semiconductor package according to claim 6, wherein the third material layer is further arranged on the first material layer, and the first material layer is provided with a part that is not covered by the third material layer.

9. The semiconductor package according to claim 1, further comprising a third semiconductor chip, wherein the third
semiconductor chip is arranged on the second semiconductor chip, the first material layer is not arranged between the third semiconductor chip and the second semiconductor chip, and the first material layer is arranged on a surface of the third semiconductor chip distal to the second semiconductor chip.

10. The semiconductor package according to claim 9, wherein a second material layer is arranged between the third semiconductor chip and the second semiconductor chip, and the second material layer is provided with the first-type filler distributed therein.

11. The semiconductor package according to claim 9, wherein the third semiconductor chip and the second semiconductor chip are electrically connected by direct bonding.

12. The semiconductor package according to claim 1, wherein the first material layer is further provided with a conductive structure that electrically connects the first semiconductor chip and the second semiconductor chip, and the first material layer at least surrounds part of the conductive structure.

13. The semiconductor package according to claim 12, wherein the conductive structure comprises a first contact pad connecting the first semiconductor chip, a second contact pad connecting the second semiconductor chip, and an intermediate interconnection structure connecting the first contact pad and the second contact pad, the first material layer surrounding the intermediate interconnection structure.

14. A semiconductor package, comprising:
a buffer chip;
a core chip arranged on the buffer chip; and
a first material layer that at least partially surrounds the buffer chip and the core chip, wherein
the first material layer comprises a non-conductive substrate as well as a first-type filler and a second-type filler that are distributed in the non-conductive substrate, an average particle size of the first-type filler being different from an average particle size of the second-type filler.
